(19) United States
(12) Patent Application Publication
(10) Pub. No.: US 2024/0256278 A1
(43) Pub. Date: Aug. 1, 2024

(54) MEMORY AND STORAGE DEVICE FOR FOGGY-PROGRAMMING AND FINE-PROGRAMMING TARGET DATA, AND OPERATING METHOD THEREOF

(71) Applicant: SK hynix Inc., Icheon (KR)

(72) Inventors: Jung Ae KIM, Icheon (KR); Tae Ha KIM, Icheon (KR)

(21) Appl. No.: 18/333,376

(22) Filed: Jun. 12, 2023

(30) Foreign Application Priority Data
Jan. 30, 2023 (KR) 10-2023-0011800

(51) Int. Cl. G06F 9/30

(52) U.S. Cl. CPC G06F 9/30043

(57) ABSTRACT

A storage device may receive a program command requesting to program target data, determine a foggy-program address and a fine-program address, receive the target data, copy the target data to a buffer, and foggy-program the target data to the foggy program address and fine-programs the target data to the fine-program address.

### CROSS-REFERENCE TO RELATED APPLICATION

The present application claims priority under 35 U.S.C. 119(a) to Korean patent application number 10-2023-0011800 filed on Jan. 30, 2023, which is incorporated herein by reference in its entirety.

### TECHNICAL FIELD

The embodiments of the present disclosure relate to a memory and a storage device for foggy-programming and fine-programming target data, and an operating method thereof.

### BACKGROUND

A storage device is a device for storing data based on a request from an external device such as a computer, a mobile terminal such as a smart phone or tablet, or various electronic devices.

The storage device may include a memory and a controller for controlling the memory (e.g., volatile memory/non-volatile memory). The controller may receive a command from an external device, and execute or control operations to read, write, or erase data in the memory based on the command.

In the case of writing data, the memory may write the data in a foggy-fine program method. In this case, the memory may perform a foggy-program on the data and then, perform a fine-program on the data after a predetermined time has elapsed.

### SUMMARY

Embodiments of the disclosure may provide a memory, a storage device including the memory, and an operating method thereof, capable of solving a problem of re-reading target data in order to fine-program the target data after the target data has been foggy-programmed.

In addition, embodiments of the disclosure may provide a memory, a storage device including the memory, and an operating method thereof, capable of reducing the cost of retaining target data until the target data is fine-programmed.

In one aspect, embodiments of the disclosure may provide a memory including i) a plurality of memory blocks, ii) a buffer configured to cache data that is to be programmed into the plurality of memory blocks, and iii) a control logic configured to receive a program command requesting programming of target data, determine, after receiving the program command, a foggy-program address being an address indicating a first location in which the target data is to be foggy-programmed, and a fine-program address being an address indicating a second location in which the target data is to be fine-programmed, the first location and the second location being included in the plurality of memory blocks, receive the target data, copy the target data to the first location indicated by the buffer, foggy-program the target data to the foggy-program address, and fine-program the target data to the second location indicated by the fine-program address.

In another aspect, embodiments of the disclosure may provide a memory operating method including i) receiving a program command requesting to program target data, ii) determining a foggy-program address being an address indicating a first location in which the target data is to be foggy-programmed, and a fine-program address being an address indicating a second location in which the target data is to be fine-programmed, the first location and the second location being included in a plurality of memory blocks, iii) receiving the target data, iv) copying the target data to a buffer that is configured to cache data to be programmed into the plurality of memory blocks, v) foggy-programming the target data to the first location, and vi) fine-programming the target data to the second location.

In another aspect, embodiments of the disclosure may provide a storage device including i) a memory including a plurality of memory blocks, a buffer configured to cache data that is to be programmed into the plurality of memory blocks, and a control logic configured to receive a program command requesting to program target data, determine, after receiving the program command, a foggy-program address being an address indicating a first location in which the target data is to be foggy-programmed and a fine-program address being an address indicating a second location in which the target data is to be fine-programmed, receive the target data, copy the target data to the buffer, foggy-program the target data to the first location indicated by the foggy-program address, and fine-program the target data to the second location indicated by the fine-program address, and ii) a controller configured to transmit the program command and the target data to the memory.

According to the embodiments of the present disclosure, it is possible to solve the problem of re-reading the target data in order to fine-program the target data, and reduce the cost of retaining the target data until the target data is fine-programmed.

### BRIEF DESCRIPTION OF THE DRAWINGS

FIG. 1 is a schematic configuration diagram of a storage device according to an embodiment of the disclosure.

FIG. 2 is a block diagram schematically illustrating a memory of FIG. 1.

FIG. 3 illustrates a schematic structure of a memory according to embodiments of the present disclosure.

FIG. 4 is a flowchart illustrating an operation of a memory according to embodiments of the present disclosure.

FIG. 5 illustrates an operation of receiving a program command, address information, and target data by a memory according to embodiments of the present disclosure.

FIG. 6 illustrates an operation in which a memory determines a foggy-program address and a fine-program address according to embodiments of the present disclosure.

FIGS. 7 to 9 illustrate an operation of programming target data by a memory according to embodiments of the present disclosure.

FIG. 10 illustrates a memory operating method according to embodiments of the present disclosure.

### DETAILED DESCRIPTION

Hereinafter, embodiments of the present disclosure are described in detail with reference to the accompanying drawings. Throughout the specification, reference to “an embodiment,” “another embodiment” or the like is not necessarily to only one embodiment, and different references to any such phrase are not necessarily limited to the same embodiment(s). The term “embodiments” when used herein does not necessarily refer to all embodiments.

Various embodiments of the present invention are described below in more detail with reference to the accompanying drawings. However, the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing methods herein.

When implemented at least partially in software, the controllers, processors, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device.

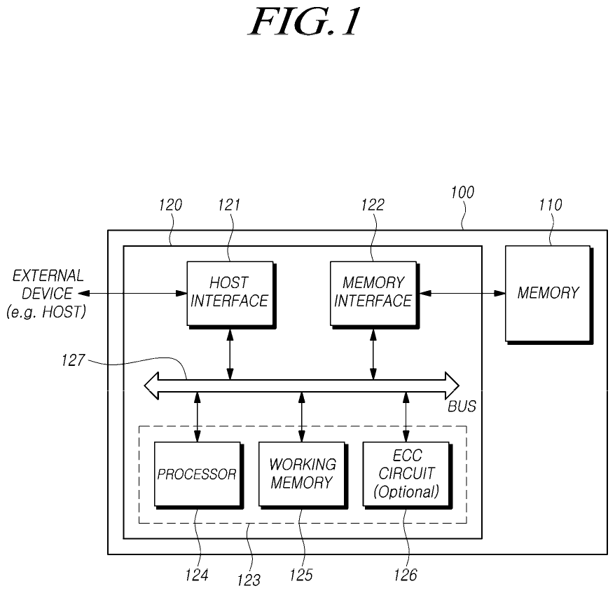

FIG. 1 is a schematic configuration diagram of a storage device 100 according to an embodiment of the disclosure.

Referring to FIG. 1, the storage device 100 may include a memory 110 that stores data and a controller 120 that controls the memory 110.

The memory 110 includes a plurality of memory blocks, and operates in response to the control of the controller 120. Operations of the memory 110 may include, for example, a read operation, a program operation (also referred to as a write operation) and an erase operation.

The memory 110 may include a memory cell array including a plurality of memory cells (also simply referred to as “cells”) that store data. Such a memory cell array may exist in a memory block.

For example, the memory 110 may be realized in various types of memory such as a DDR SDRAM (double data rate synchronous dynamic random access memory), an LPDDR4 (low power double data rate 4) SDRAM, a GDDR (graphics double data rate) SDRAM, an LPDDR (low power DDR), an RDRAM (Rambus dynamic random access memory), a NAND flash memory, a 3D NAND flash memory, a NOR flash memory, a resistive random access memory (RRAM), a phase-change memory (PRAM), a magnetoresistive random access memory (MRAM), a ferroelectric random access memory (FRAM) and a spin transfer torque random access memory (STT-RAM).

The memory 110 may be implemented as a three-dimensional array structure. For example, embodiments of the disclosure may be applied to a charge trap flash (CTF) in which a charge storage layer is configured by a dielectric layer and a flash memory in which a charge storage layer is configured by a conductive floating gate.

The memory 110 may receive a command and an address from the controller 120 and may access an area in the memory cell array that is selected by the address. In other words, the memory 110 may perform an operation indicated by the command, on the area selected by the address.

The memory 110 may perform a program operation, a read operation or an erase operation. For example, when performing the program operation, the memory 110 may program data to the area selected by the address. When performing the read operation, the memory 110 may read data from the area selected by the address. In the erase operation, the memory 110 may erase data stored in the area selected by the address.

The controller 120 may control write (program), read, erase and background operations for the memory 110. For example, background operations may include at least one from among a garbage collection (GC) operation, a wear leveling (WL) operation, a read reclaim (RR) operation, a bad block management (BBM) operation, and so forth.

The controller 120 may control the operation of the memory 110 according to a request from a device (e.g., a host) located outside the storage device 100. The controller 120, however, also may control the operation of the memory 110 regardless or in the absence of a request of the host.

The host may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a computer network, one of various electronic devices configuring a telematics network, an RFID (radio frequency identification) device, and a mobility device (e.g., a vehicle, a robot or a drone) capable of driving under human control or autonomous driving, as non-limiting examples. Alternatively, the host may be a virtual reality (VR) device providing 2D or 3D virtual reality images or an augmented reality (AR) device providing augmented reality images. The host may be any one of various electronic devices that require the storage device 100 capable of storing data.

The host may include at least one operating system (OS). The operating system may generally manage and control the function and operation of the host, and may provide interoperability between the host and the storage device 100. The operating system may be classified into a general operating system and a mobile operating system depending on the mobility of the host.

The controller 120 and the host may be devices that are separated from each other, or the controller 120 and the host may be integrated into one device. Hereunder, for the sake of convenience in explanation, descriptions will describe the controller 120 and the host as devices that are separated from each other.

Referring to FIG. 1, the controller 120 may include a memory interface 122 and a control circuit 123, and may further include a host interface 121.

The host interface 121 provides an interface for communication with the host. For example, the host interface 121 provides an interface that uses at least one from among various interface protocols such as a USB (universal serial bus) protocol, an MMC (multimedia card) protocol, a PCI (peripheral component interconnection) protocol, a PCI-E (PCI-express) protocol, an ATA (advanced technology attachment) protocol, a serial-ATA protocol, a parallel-ATA protocol, an SCSI (small computer system interface) protocol, an ESDI (enhanced small disk interface) protocol, an IDE (integrated drive electronics) protocol and a private protocol.

When receiving a command from the host, the control circuit 123 may receive the command through the host interface 121, and may perform an operation of processing the received command.

The memory interface 122 may be coupled with the memory 110 to provide an interface for communication with the memory 110. That is to say, the memory interface 122 may be configured to provide an interface between the memory 110 and the controller 120 in response to the control of the control circuit 123.

The control circuit 123 performs the general control operations of the controller 120 to control the operation of the memory 110. To this end, for instance, the control circuit 123 may include at least one of a processor 124 and a working memory 125, and may optionally include an error detection and correction circuit (ECC circuit) 126.

The processor 124 may control general operations of the controller 120, and may perform a logic calculation. The processor 124 may communicate with the host through the host interface 121, and may communicate with the memory 110 through the memory interface 122.

The processor 124 may perform the function of a flash translation layer (FTL). The processor 124 may translate a logical block address (LBA), provided by the host, into a physical block address (PBA) through the flash translation layer (FTL). The flash translation layer (FTL) may receive the logical block address (LBA) and translate the logical block address (LBA) into the physical block address (PBA), by using a mapping table.

There are various address mapping methods of the flash translation layer, depending on a mapping unit. Representative address mapping methods include a page mapping method, a block mapping method and a hybrid mapping method.

The processor 124 may randomize data received from the host. For example, the processor 124 may randomize data received from the host by using a set randomizing seed. The randomized data may be provided to the memory 110, and may be programmed to a memory cell array of the memory 110.

In a read operation, the processor 124 may derandomize data received from the memory 110. For example, the processor 124 may derandomize data received from the memory 110 by using a derandomizing seed. The derandomized data may be outputted to the host.

The processor 124 may execute firmware to control the operation of the controller 120. Namely, in order to control the general operation of the controller 120 and perform a logic calculation, the processor 124 may execute (drive) firmware loaded in the working memory 125 upon booting. Hereafter, an operation of the storage device 100 according to embodiments of the disclosure will be described as implementing a processor 124 that executes firmware in which the corresponding operation is defined.

Firmware, as a program to be executed in the storage device 100 to drive the storage device 100, may include various functional layers. For example, the firmware may include binary data in which codes for executing the functional layers, respectively, are defined.

For example, the firmware may include at least one from among a flash translation layer (FTL), which performs a translating function between a logical address requested to the storage device 100 from the host and a physical address of the memory 110; a host interface layer (HIL), which serves to analyze a command requested to the storage device 100 as a storage device from the host and transfer the command to the flash translation layer (FTL); and a flash interface layer (FIL), which transfers a command, instructed from the flash translation layer (FTL), to the memory 110.

Such firmware may be loaded in the working memory 125 from, for example, the memory 110 or a separate nonvolatile memory (e.g., a ROM or a NOR Flash) located outside the memory 110. The processor 124 may first load all or a part of the firmware in the working memory 125 when executing a booting operation after power-on.

The processor 124 may perform a logic calculation, which is defined in the firmware loaded in the working memory 125, to control the general operation of the controller 120. The processor 124 may store a result of performing the logic calculation defined in the firmware, in the working memory 125. The processor 124 may control the controller 120 according to a result of performing the logic calculation defined in the firmware such that the controller 120 generates a command or a signal. When a part of firmware, in which a logic calculation to be performed is defined, is stored in the memory 110, but not loaded in the working memory 125, the processor 124 may generate an event (e.g., an interrupt) for loading the corresponding part of the firmware into the working memory 125 from the memory 110.

The processor 124 may load metadata necessary for driving firmware from the memory 110. The metadata, as data for managing the memory 110, may include for example management information on user data stored in the memory 110.

Firmware may be updated while the storage device 100 is manufactured or while the storage device 100 is operating. The controller 120 may download new firmware from the outside of the storage device 100 and update existing firmware with the new firmware.

To drive the controller 120, the working memory 125 may store necessary firmware, a program code, a command and data. The working memory 125 may be a volatile memory that includes, for example, at least one from among an SRAM (static RAM), a DRAM (dynamic RAM) and an SDRAM (synchronous DRAM).

The error detection and correction circuit 126 may detect an error bit of target data, and correct the detected error bit by using an error correction code. The target data may be, for example, data stored in the working memory 125 or data read from the memory 110.

The error detection and correction circuit 126 may decode data by using an error correction code. The error detection and correction circuit 126 may be realized by various code decoders. For example, a decoder that performs unsystematic code decoding or a decoder that performs systematic code decoding may be used.

For example, the error detection and correction circuit 126 may detect an error bit by the unit of a set sector in each of the read data, when each read data is constituted by a plurality of sectors. A sector may mean a data unit that is smaller than a page, which is the read unit of a flash memory. Sectors constituting each read data may be matched with one another using an address.

The error detection and correction circuit 126 may calculate a bit error rate (BER), and may determine whether an error is correctable or not, by sector units. For example, when a bit error rate (BER) is higher than a reference value, the error detection and correction circuit 126 may determine that a corresponding sector is uncorrectable or a fail. On the other hand, when a bit error rate (BER) is lower than the reference value, the error detection and correction circuit 126 may determine that a corresponding sector is correctable or a pass.

The error detection and correction circuit 126 may perform an error detection and correction operation sequentially for all read data. In the case where a sector included in read data is correctable, the error detection and correction circuit 126 may omit an error detection and correction operation for a corresponding sector for next read data. If the error detection and correction operation for all read data is ended in this way, then the error detection and correction circuit 126 may detect a sector which is uncorrectable in read data last. There may be one or more sectors that are determined to be uncorrectable. The error detection and correction circuit 126 may transfer information (e.g., address information) regarding a sector which is determined to be uncorrectable to the processor 124.

A bus 127 may be configured to provide channels among the components 121, 122, 124, 125 and 126 of the controller 120. The bus 127 may include, for example, a control bus for transferring various control signals, commands and the like, a data bus for transferring various data, and so forth.

Some components among the above-described components 121, 122, 124, 125 and 126 of the controller 120 may be omitted, or some components among the above-described components 121, 122, 124, 125 and 126 of the controller 120 may be integrated into one component. In addition to the above-described components 121, 122, 124, 125 and 126 of the controller 120, one or more other components may be added.

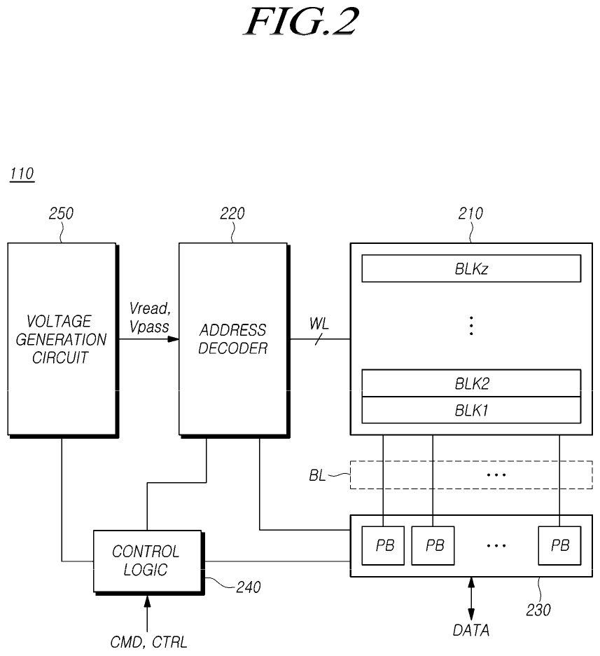

Hereinbelow, the memory 110 will be described in further detail with reference to FIG. 2.

FIG. 2 is a block diagram schematically illustrating the memory 110 of FIG. 1.

Referring to FIG. 2, the memory 110 may include a memory cell array 210, an address decoder 220, a read and write circuit 230, a control logic 240, and a voltage generation circuit 250.

The memory cell array 210 may include a plurality of memory blocks BLK1 to BLKz (where z is a natural number of 2 or greater).

In the plurality of memory blocks BLK1 to BLKz, a plurality of word lines WL and a plurality of bit lines BL may be disposed, and a plurality of memory cells (MC) may be arranged.

The plurality of memory blocks BLK1 to BLKz may be coupled with the address decoder 220 through the plurality of word lines WL. The plurality of memory blocks BLK1 to BLKz may be coupled with the read and write circuit 230 through the plurality of bit lines BL.

Each of the plurality of memory blocks BLK1 to BLKz may include a plurality of memory cells. For example, the plurality of memory cells may be nonvolatile memory cells, and may be configured by nonvolatile memory cells that have vertical channel structures.

The memory cell array 210 may be configured by a memory cell array of a two-dimensional structure or may be configured by a memory cell array of a three-dimensional structure.

Each of the plurality of memory cells included in the memory cell array 210 may store at least 1-bit data. For instance, each of the plurality of memory cells included in the memory cell array 210 may be a signal level cell (SLC) that stores 1-bit data. In another instance, each of the plurality of memory cells included in the memory cell array 210 may be a multi-level cell (MLC) that stores 2-bit data. In still another instance, each of the plurality of memory cells included in the memory cell array 210 may be a triple level cell (TLC) that stores 3-bit data. In yet another instance, each of the plurality of memory cells included in the memory cell array 210 may be a quad level cell (QLC) that stores 4-bit data. In a further instance, the memory cell array 210 may include a plurality of memory cells, each of which stores 5 or more-bit data.

The number of bits of data stored in each of the plurality of memory cells may be dynamically determined. For example, a single-level cell that stores 1-bit data may be changed to a triple-level cell that stores 3-bit data.

Referring to FIG. 2, the address decoder 220, the read and write circuit 230, the control logic 240 and the voltage generation circuit 250 may operate as a peripheral circuit that drives the memory cell array 210.

The address decoder 220 may be coupled to the memory cell array 210 through the plurality of word lines WL.

The address decoder 220 may be configured to operate in response to the control of the control logic 240.

The address decoder 220 may receive an address through an input/output buffer in the memory 110. The address decoder 220 may be configured to decode a block address in the received address. The address decoder 220 may select at least one memory block depending on the decoded block address.

The address decoder 220 may receive a read voltage Vread and a pass voltage Vpass from the voltage generation circuit 250.

The address decoder 220 may apply the read voltage Vread to a selected word line WL in a selected memory block during a read operation, and may apply the pass voltage Vpass to the remaining unselected word lines WL.

The address decoder 220 may apply a verify voltage generated in the voltage generation circuit 250 to a selected word line WL in a selected memory block in a program verify operation, and may apply the pass voltage Vpass to the remaining unselected word lines WL.

The address decoder 220 may be configured to decode a column address in the received address. The address decoder 220 may transmit the decoded column address to the read and write circuit 230.

A read operation and a program operation of the memory 110 may be performed by the unit of a page. An address received when a read operation or a program operation is requested may include at least one from among a block address, a row address and a column address.

The address decoder 220 may select one memory block and one word line depending on a block address and a row address. A column address may be decoded by the address decoder 220 and be provided to the read and write circuit 230.

The address decoder 220 may include at least one from among a block decoder, a row decoder, a column decoder and an address buffer.

The read and write circuit 230 may include a plurality of page buffers PB. The read and write circuit 230 may operate as a read circuit in a read operation of the memory cell array 210, and may operate as a write circuit in a write operation of the memory cell array 210.

The read and write circuit 230 described above may also be referred to as a page buffer circuit or a data register circuit that includes a plurality of page buffers PB. The read and write circuit 230 may include data buffers that take charge of a data processing function, and may further include cache buffers that take charge of a caching function.

The plurality of page buffers PB may be coupled to the memory cell array 210 through the plurality of bit lines BL. The plurality of page buffers PB may continuously supply sensing current to bit lines BL coupled with memory cells to sense threshold voltages (Vth) of the memory cells in a read operation and a program verify operation, and may latch sensing data by sensing, through sensing nodes, changes in the amounts of current flowing, depending on the programmed states of the corresponding memory cells.

The read and write circuit 230 may operate in response to page buffer control signals outputted from the control logic 240.

In a read operation, the read and write circuit 230 temporarily stores read data by sensing data of memory cells, and then, outputs data DATA to the input/output buffer of the memory 110. As an exemplary embodiment, the read and write circuit 230 may include a column select circuit in addition to the page buffers PB or the page registers.

The control logic 240 may be coupled with the address decoder 220, the read and write circuit 230 and the voltage generation circuit 250. The control logic 240 may receive a command CMD and a control signal CTRL through the input/output buffer of the memory 110.

The control logic 240 may be configured to control general operations of the memory 110 in response to the control signal CTRL. The control logic 240 may output control signals for adjusting the precharge potential levels of the sensing nodes of the plurality of page buffers PB.

The control logic 240 may control the read and write circuit 230 to perform a read operation of the memory cell array 210. The voltage generation circuit 250 may generate the read voltage Vread and the pass voltage Vpass used in a read operation, in response to a voltage generation circuit control signal output from the control logic 240.

Each memory block of the memory 110 described above may be configured by a plurality of pages corresponding to a plurality of word lines WL and a plurality of strings corresponding to a plurality of bit lines BL.

In a memory block BLK, a plurality of word lines WL and a plurality of bit lines BL may be disposed to intersect with each other. For example, each of the plurality of word lines WL may be disposed in a row direction, and each of the plurality of bit lines BL may be disposed in a column direction. In another example, each of the plurality of word lines WL may be disposed in a column direction, and each of the plurality of bit lines BL may be disposed in a row direction.

A memory cell may be coupled to one of the plurality of word lines WL and one of the plurality of bit lines BL. A transistor may be disposed in each memory cell.

For example, a transistor disposed in each memory cell (MC) may include a drain, a source and a gate. The drain (or source) of the transistor may be coupled with a corresponding bit line BL directly or via another transistor. The source (or drain) of the transistor may be coupled with a source line (which may be the ground) directly or via another transistor. The gate of the transistor may include a floating gate, which is surrounded by a dielectric, and a control gate to which a gate voltage is applied from a word line WL.

In each memory block, a first select line (also referred to as a source select line or a drain select line) may be additionally disposed outside a first outermost word line more adjacent to the read and write circuit 230 between two outermost word lines, and a second select line (also referred to as a drain select line or a source select line) may be additionally disposed outside a second outermost word line between the two outermost word lines.

At least one dummy word line may be additionally disposed between the first outermost word line and the first select line. At least one dummy word line may also be additionally disposed between the second outermost word line and the second select line.

A read operation and a program operation (write operation) of the memory block described above may be performed by the unit of a page, and an erase operation may be performed by the unit of a memory block.

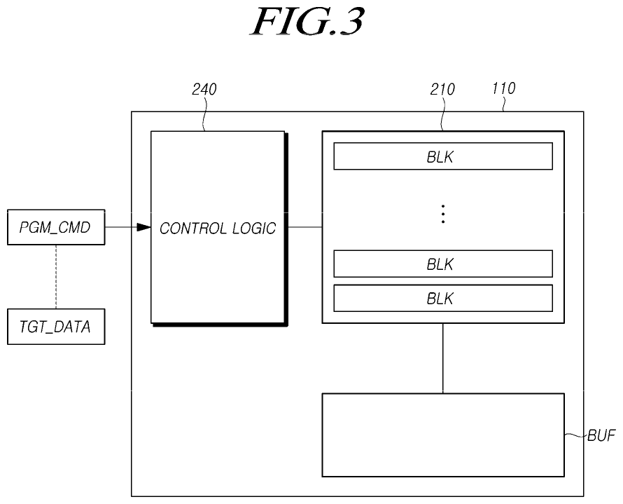

FIG. 3 illustrates a schematic structure of a memory 110 according to embodiments of the present disclosure.

Referring to FIG. 3, the memory 110 may include a memory cell array 210 that includes a plurality of memory blocks BLK. The plurality of memory blocks BLK may correspond to the plurality of memory blocks BLK1 to BLKz shown in FIG. 2, respectively, where z is a natural number greater than or equal to 2.

In this case, each of the plurality of memory blocks BLK may include a plurality of pages. Each of the plurality of pages may include a plurality of memory cells coupled to the same word line. For example, the plurality of memory cells may be quad-level cells (QLCs) or triple-level cells (TLCs).

In addition, the memory 110 may include a buffer BUF. The buffer BUF may cache data to be programmed into the plurality of memory blocks BLK. In order for the memory 110 to program data into the plurality of memory blocks BLK, the corresponding data is required to be cached in the buffer BUF.

For example, the buffer BUF may be a page buffer PB described in FIG. 2 or a set of page buffers PB. As another example, the buffer BUF may include a volatile memory that is separate from the page buffer PB.

In addition, the memory 110 may include control logic 240. The control logic 240 may receive a program command PGM_CMD requesting programming of target data TGT_DATA and may program the target data TGT_DATA into the plurality of memory blocks BLK according to the request of the program command PGM_CMD.

For example, the memory 110 may receive the program command PGM_CMD and the target data TGT_DATA from the controller 120 described in FIG. 1. The controller 120 may transmit the program command PGM_CMD and the target data TGT_DATA to the memory 110 to process a write request received from the outside of the storage device 100.

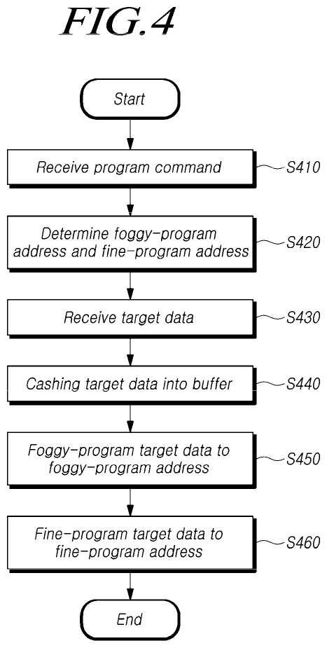

Hereinafter, it will be described a detailed operation of receiving the program command PGM_CMD and programming the target data TGT_DATA by the memory 110 with reference to FIG. 4.

FIG. 4 is a flowchart illustrating the operation of the memory 110 shown in FIG. 3 according to embodiments of the present disclosure. The operation will be described with reference to the memory 110 shown in FIG. 3.

Referring to FIGS. 3 and 4, the control logic 240 of the memory 110 may receive the program command PGM_CMD requesting programming of the target data TGT_DATA (S410). In this case, the size of the target data TGT_DATA may be a page size or a multiple of the page size.

After receiving the program command PGM_CMD in step S410, the control logic 240 may receive address information ADDR_INFO and determine a foggy-program address and a fine-program address based on the address information ADDR_INFO (S420).

The foggy-program address may indicate an address of a location in which the target data TGT_DATA is to be foggy-programmed. The fine-program address may indicate an address of a location where the target data TGT_DATA is to be fine-programmed.

When programming the target data TGT_DATA, the memory 110 may program the target data TGT_DATA by foggy-programming the target data TGT_DATA and then fine-programming the target data TGT_DATA, instead of programming the target data TGT_DATA in a one-shot programming method.

When the memory 110 foggy-programs the target data TGT_DATA, memory cells may be programmed into an erase state or one of a plurality of intermediate program states. In this case, threshold voltage distributions of the memory cells programmed with the target data TGT_DATA may have overlapping portions.

After foggy-programming the target data TGT_DATA, the memory 110 may fine-program the target data TGT_DATA to more finely adjust the threshold voltage distributions of the memory cells programmed with the target data TGT_DATA. When the memory 110 fine-programs the target data TGT_DATA, the memory cells programmed with the target data TGT_DATA may be programmed into an erase state or one of a plurality of program states.

After the fine-programming of the target data TGT_DATA is completed, the threshold voltage distributions of the memory cells programmed with the target data TGT_DATA may be completely separated from each other without overlapping portions.

In a state in which the target data TGT_DATA is foggy-programmed, there may be impossible to read the target data TGT_DATA from the outside of the memory 110. After the target data TGT_DATA is fine-programmed, it is possible to read the target data TGT_DATA from the outside of the memory 110.

After the control logic 240 determines the foggy-program address and the fine-program address in step S420, the control logic 240 may receive the target data TGT_DATA (S430). In FIG. 4, it has been described the case where the control logic 240 receives the target data TGT_DATA after determining the foggy-program address and the fine-program address. However, embodiments are not limited thereto. In other embodiments, the control logic 240 may receive the target data TGT_DATA while determining the foggy-program address and the fine-program address, or may determine the foggy-program address and fine-program address after receiving the target data TGT_DATA.

The control logic 240 may cash the target data TGT_DATA received in step S430 into the buffer BUF (S440).

The control logic 240 may foggy-program the target data TGT_DATA in memory cells indicated by the foggy-program address (S450).

Thereafter, the control logic 240 may fine-program the target data TGT_DATA in memory cells indicated by the fine-program address (S460).

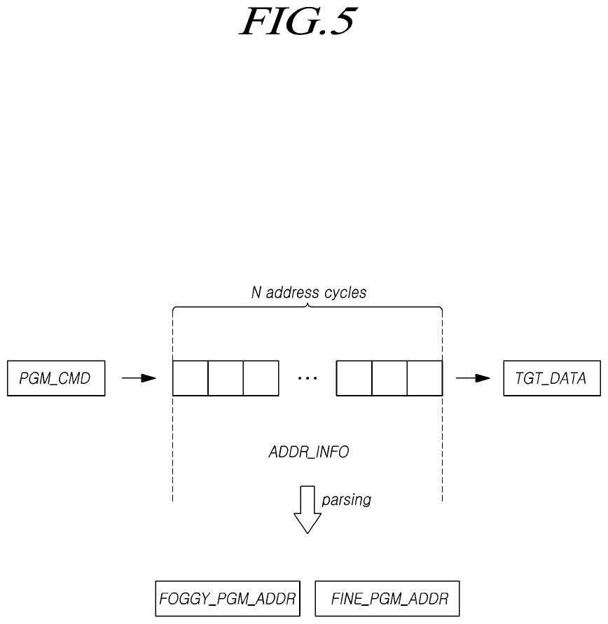

Hereinafter, the above steps S410 to S430 shown in FIG. 4 will be described in detail with reference to FIG. 5.

FIG. 5 illustrates an operation of receiving a program command PGM_CMD, address information ADDR_INFO, and target data TGT_DATA by a memory 110 according to embodiments of the present disclosure. The operation will be described with reference to the memory 110 shown in FIG. 3.

Referring to FIGS. 3 and 5, the control logic 240 of the memory 110 may first receive the program command PGM_CMD, and then, may receive the address information ADDR_INFO during N address cycles (N is a natural number greater than or equal to 2).

Then, the control logic 240 may parse the address information ADDR_INFO to determine a foggy-program address FOGGY_PGM_ADDR and a fine-program address FINE_PGM_ADDR. In this case, the control logic 240 may execute an operation of parsing the address information ADDR_INFO using an address parser circuit. In an embodiment, the address parser circuit may be separate from the control logic 240. In another embodiment, the address parser circuit may be integrated into the control logic 240.

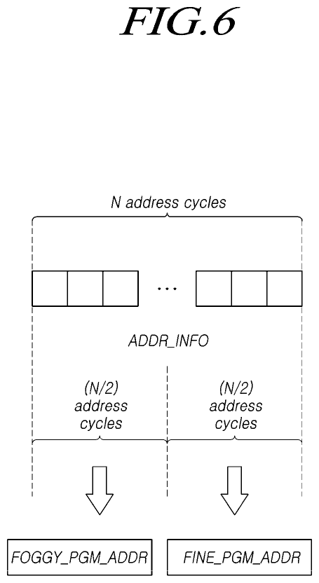

Hereinafter, it will be described with reference to FIG. 6 an example in which the control logic 240 parses the address information ADDR_INFO to determine the foggy-program address FOGGY_PGM_ADDR and the fine-program address FINE_PGM_ADDR.

FIG. 6 illustrates an operation in which the memory 110 determines the foggy-program address FOGGY_PGM_ADDR and the fine-program address FINE_PGM_ADDR according to embodiments of the present disclosure.

Referring to FIGS. 3 and 6, the control logic 240 of the memory 110 may determine a first part of the address information ADDR_INFO that is received during preceding (N/2) address cycles among the N address cycles described in FIG. 5, as the foggy-program address FOGGY_PGM_ADDR.

In addition, the control logic 240 may determine a second part of the address information ADDR_INFO that is received during subsequent (N/2) address cycles among the N address cycles, as the fine-program address FINE_PGM_ADDR. The subsequent (N/2) address cycles follow the preceding (N/2) address cycles.

For example, in the case of receiving the address information ADDR_INFO during 10 address cycles, the control logic 240 may determine the first part of the address information ADDR_INFO that is received during preceding five address cycles, as the foggy-program address FOGGY_PGM_ADDR, and determine the second part of the address information ADDR_INFO that is received during subsequent five address cycles following the preceding five address cycles, as the fine-program address. FINE_PGM_ADDR.

In an embodiment, the foggy-program address FOGGY_PGM_ADDR and the fine-program address FINE_PGM_ADDR may be the same. That is, the location where the target data TGT_DATA is foggy-programmed and the location where the target data TGT_DATA is fine-programmed may be the same. In this case, the foggy-programmed target data TGT_DATA may be overwritten with the fine-programmed target data TGT_DATA.

Meanwhile, FIG. 6 describes a case in which the number of address cycles corresponding to the foggy-program address FOGGY_PGM_ADDR and the number of address cycles corresponding to the fine-program address FINE_PGM_ADDR are equal to (N/2) as an example. However, in other embodiments of the present disclosure, the number of address cycles corresponding to the foggy-program address FOGGY_PGM_ADDR and the number of address cycles corresponding to the fine-program address FINE_PGM_ADDR may be different from each other.

In another embodiment, the control logic 240 may determine a first part of the address information ADDR_INFO that is received during a first number of address cycles (e.g., (N*(2/3)) number of address cycles) among an N number of address cycles, as the foggy-program address FOGGY_PGM_ADDR. In this case, the control logic 240 may determine a second part of the address information ADDR_INFO that is received during a second number of address cycles (e.g., (N/3) number of address cycles) among the N number of address cycles, as the fine-program address FINE_PGM_ADDR.

In yet another embodiment, the control logic 240 may determine the first part of the address information ADDR_INFO that is received during the first number of address cycles (e.g., (N*(2/3)) number of address cycles) among the N number of address cycles, as the fine-program address FINE_PGM_ADDR, and may determine the second part of the address information ADDR_INFO that is received during the second number of address cycles (e.g., (N/3) number of address cycles) among the N number of address cycles, as the foggy-program address FOGGY_PGM_ADDR.

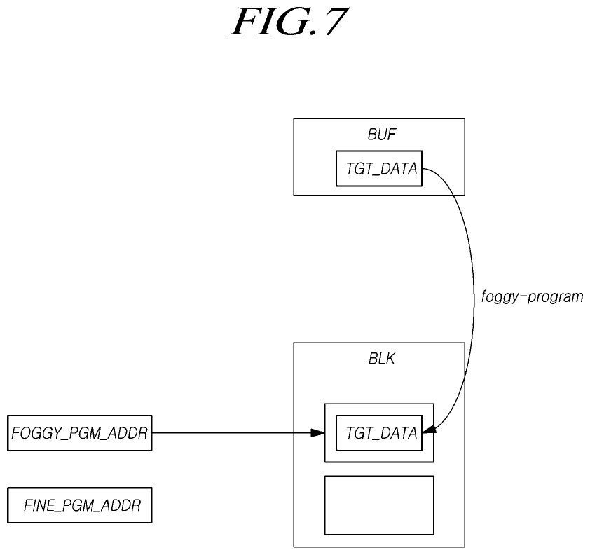

FIGS. 7 to 9 illustrate an operation of programming target data TGT_DATA by a memory 110 according to embodiments of the present disclosure. The operation will be described with reference to the memory 110 shown in FIG. 3.

FIGS. 7 to 9 illustrate a case in which the foggy-program address FOGGY_PGM_ADDR and the fine-program address FINE_PGM_ADDR are different, as an example. However, embodiments of the present disclosure are not limited to the case where the foggy-program address FOGGY_PGM_ADDR is different from the fine-program address FINE_PGM_ADDR, and the foggy-program address FOGGY_PGM_ADDR and the fine-program address FINE_PGM_ADDR may be the same.

Referring to FIGS. 3 and 7, the control logic 240 of the memory 110 may foggy-program the target data TGT_DATA cached in the buffer BUF into memory cells indicated by the foggy-program address FOGGY_PGM_ADDR. In this case, the foggy-program address FOGGY_PGM_ADDR may indicate memory cells in a specific area (e.g., page) of a specific memory block BLK included in the memory 110.

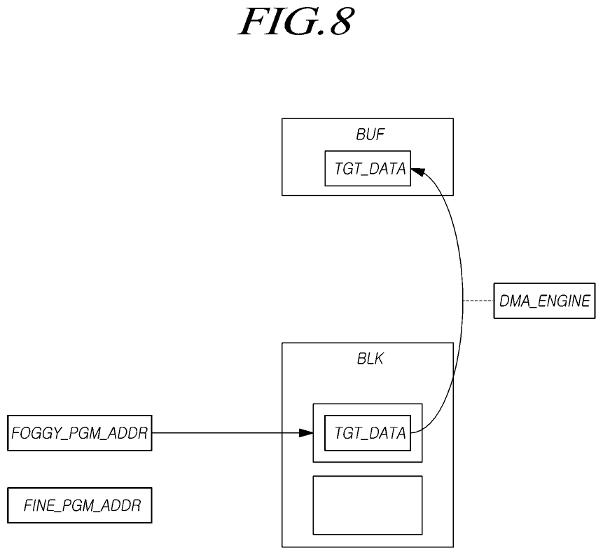

Referring to FIG. 8, the control logic 240 may copy the foggy-programmed target data TGT_DATA that is stored in the memory cells indicated by the foggy-program address FOGGY_PGM_ADDR to the buffer BUF.

The target data TGT_DATA cached in the buffer BUF may be lost before executing the fine-programming for the target data TGT_DATA due to various reasons.

For example, if power-off occurs before executing the fine-programming for the target data TGT_DATA, the target data TGT_DATA cached in the buffer BUF may be lost.

As another example, if a program operation for other data is performed in the buffer BUF before executing the fine-programming for the target data TGT_DATA, the target data TGT_DATA cached in the buffer BUF may be lost.

In this case, the control logic 240 may copy the foggy-programmed target data TGT_DATA that is stored in the memory cells indicated by the foggy-program address FOGGY_PGM_ADDR to the buffer BUF in order to execute the fine-programming for the target data TGT_DATA.

The control logic 240 copies the foggy-programmed target data TGT_DATA to the buffer BUF, so that it is not required to read again the target data TGT_DATA from the controller 120. Therefore, it is possible to prevent an increase in the possibility of occurrence of a disturbance due to an increase in a read count that is caused by re-reading the target data TGT_DATA. In addition, it is possible to prevent the efficiency of garbage collection from decreasing due to a time taken to re-read the target data TGT_DATA.

In addition, since the controller 120 does not need to retain the target data TGT_DATA in the buffer BUF until the fine-program operation is completed after the foggy-program operation is performed, it is possible to reduce the costs for retaining the target data TGT_DATA in the buffer BUF.

Meanwhile, when copying the foggy-programmed target data TGT_DATA to the buffer BUF, the control logic 240 may request a DMA engine DMA_ENGINE to copy the foggy-programmed target data TGT_DATA to the buffer BUF.

The DMA engine DMA_ENGINE may copy data stored in a plurality of memory blocks to the buffer BUF through direct memory access (DMA). Accordingly, the control logic 240 may utilize resources to execute another operation instead of directly performing the operation of copying the foggy-programmed target data TGT_DATA to the buffer BUF.

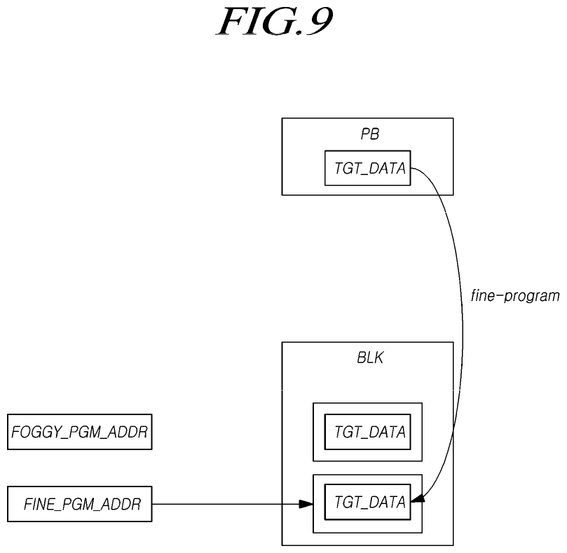

Referring to FIG. 9, the control logic 240 may fine-program the target data TGT_DATA cached in the buffer BUF into memory cells indicated by the fine-program address FINE_PGM_ADDR. The target data TGT_DATA cached in the buffer BUF may be the foggy-programmed target data TGT_DATA copied to the buffer BUF.

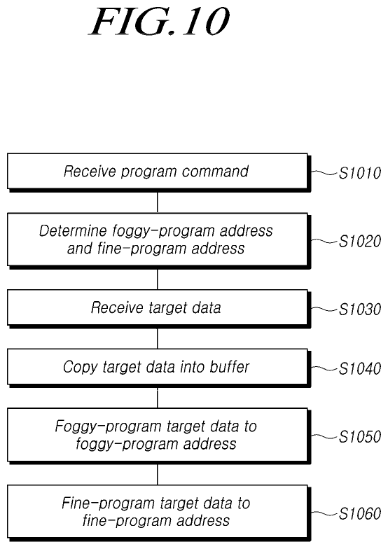

FIG. 10 illustrates an operating method of a memory according to embodiments of the present disclosure. The operating method will be described with reference to the memory 110 shown in FIG. 3.

Referring to FIG. 10, the operating method of the memory 110 may include receiving a program command PGM_CMD requesting programming of target data TGT_DATA (S1010).

In addition, the operating method of the memory 110 may include determining a foggy-program address FOGGY_PGM_ADDR indicating an address of a location in which the target data TGT_DATA is to be foggy-programmed and a fine-program address FINE_PGM_ADDR indicating an address of a location where the target data TGT_DATA is to be fine-programmed (S1020).

For example, step S1020 may include receiving address information ADDR_INFO during an N number of address cycles (N is a natural number equal to or greater than 2) after receiving the program command PGM_CMD, and parsing the received address information ADDR_INFO to determine the foggy-program address FOGGY_PGM_ADDR and the fine-program address FINE_PGM_ADDR.

In step S1020, address information received during preceding (N/2) number of address cycles among the N number of address cycles may be determined as the foggy-program address FOGGY_PGM_ADDR, and address information received during the next (N/2) number of address cycles among the N number of address cycles may be determined as the fine-program address FINE_PGM_ADDR.

The operating method of the memory 110 may include receiving the target data TGT_DATA (S1030).

The operating method of the memory 110 may include copying the target data TGT_DATA into the buffer BUF (S1040). The buffer BUF may cache data to be programmed into a plurality of memory blocks.

The operating method of the memory 110 may include foggy-programming the target data TGT_DATA into memory cells indicated by the foggy-program address FOGGY_PGM_ADDR (S1050).

The operating method of the memory 110 may include fine-programming the target data TGT_DATA into memory cells indicated by the fine-program address FINE_PGM_ADDR (S1060).

Meanwhile, before fine-programming the target data TGT_DATA to the memory cells indicated by the fine-program address FINE_PGM_ADDR after foggy-programming the target data TGT_DATA to the memory cells indicated by the foggy-program address FOGGY_PGM_ADDR, the operating method of the memory 110 may further include copying the foggy-programmed target data TGT_DATA stored in the memory cells indicated by the foggy-program address FOGGY_PGM_ADDR to the buffer BUF. In this case, the fine-programming of the target data TGT_DATA may be performed by programming the foggy-programmed target data TGT_DATA copied to the buffer BUF into the memory cells indicated by the fine-program address FINE_PGM_ADDR.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A memory comprising:
a plurality of memory blocks;
a buffer configured to cache data that is to be programmed into the plurality of memory blocks; and
a control logic,
wherein the control logic is configured to:
receive a program command requesting programing of target data;
determine, after receiving the program command, a foggy-program address being an address indicating a first location in which the target data is to be foggy-programmed, and a fine-program address being an address indicating a second location in which the target data is to be fine-programmed, the first location and the second location being included in the plurality of memory blocks;
receive the target data;
copy the target data to the buffer;
foggy-program the target data to the first location indicated by the foggy-program address; and
fine-program the target data to the second location indicated by the fine-program address.

2. The memory of claim 1, wherein the control logic is configured to receive, after receiving the program command, the address information during N address cycles, and parse the address information to determine the foggy-program address and the fine-program address, wherein N is a natural number of two or more.

3. The memory of claim 2, wherein the control logic determines address information received during preceding (N/2) address cycles among the N address cycles as the foggy-program address, and determines address information received during subsequent (N/2) address cycles among the N address cycles as the fine-program address.

4. The memory of claim 3, wherein the foggy-program address and the fine-program address indicate a same location.

5. The memory of claim 1, wherein, before fine-programming the target data to the second location after foggy-programming the target data to the first location, the control logic copies the target data foggy-programmed to the first location to the buffer.

6. The memory of claim 5, further comprising a direct memory access (DMA) engine for copying data stored in the plurality of memory blocks to the buffer through DMA,
wherein the control logic requests the DMA engine to copy the target data foggy-programmed to the first location to the buffer.

7. The memory of claim 5, wherein the control logic fine-programs the target data foggy-programmed and copied to the buffer to the second location.

8. An operating method of a memory comprising:
receiving a program command requesting programming of target data;
determining a foggy-program address being an address indicating a first location in which the target data is to be foggy-programmed, and a fine-program address being an address indicating a second location in which the target data is to be fine-programmed, the first location and the second location being included in a plurality of memory blocks;
receiving the target data;
copying the target data to a buffer that is configured to cache data to be programmed into the plurality of memory blocks;
foggy-programming the target data to the first location; and
fine-programming the target data to the second location.

9. The operating method of claim 8, wherein the determining a foggy-program address and a fine-program address comprises:
receiving, after receiving the program command, the address information during N address cycles, wherein N is a natural number of two or more; and
parsing the address information to determine the foggy-program address and the fine-program address.

10. The operating method of claim 9, wherein the determining a foggy-program address and a fine-program address comprises:
determining address information received during preceding (N/2) address cycles among the N address cycles as the foggy-program address; and
determining address information received during subsequent (N/2) address cycles among the N address cycles as the fine-program address.

11. The operating method of claim 8, further comprising, before fine-programming the target data to the second location after foggy-programming the target data to the first location, copying the target data foggy-programmed to the first location to the buffer.

12. The operating method of claim 11, wherein the fine-programming comprises fine-programming the target data foggy-programmed and copied to the buffer to the second location.

13. A storage device comprising:
a memory comprising:
a plurality of memory blocks;
a buffer configured to cache data that is to be programmed into the plurality of memory blocks; and
a control logic,
wherein the control logic is configured to:
receive a program command requesting programming of target data;
determine, after receiving the program command, a foggy-program address being an address indicating a first location in which the target data is to be foggy-programmed, a fine-program address being an address indicating a second location in which the target data is to be fine-programmed;
receive the target data;
copy the target data to the buffer;
foggy-program the target data to the first location indicated by the foggy-program address; and
fine-program the target data to the second location indicated by the fine-program address; and
a controller configured to transmit the program command and the target data to the memory.

14. The storage device of claim 13, wherein, before fine-programming the target data to the second location after foggy-programming the target data to the first location, the control logic copies the target data foggy-programmed to the first location to the buffer.

15. The storage device of claim 14, wherein the control logic fine-programs the target data foggy-programmed and copied to the buffer to the second location.
